(19) United States
(12) Patent Application Publication
(10) Pub. No.: US 2011/0061234 A1
(43) Pub. Date: Mar. 17, 2011

(54) Method For Fabricating Carrier Board Having No Conduction Line

(76) Inventors: Jun-Chung Hsu, Taoyuan (TW); Yi-Fan Kao, Taipei (TW)

(21) Appl. No.: 12/548,418

(22) Filed: Sep. 15, 2009

(51) Int. Cl. H05K 3/10

(52) U.S. Cl. 29/846

(57) ABSTRACT

A method for fabricating a carrier board having no conduction line is provided. The fabricating method includes: providing a support plate having a detachable metal layer; providing a plating current via the support plate and the detachable metal layer to plate on the detachable metal layer to in sequence configure an etching resist layer and a plating metal layer; and then gradually completing other circuit layers by a compression laminating process with the support plate providing the plating current. After the entire plating process has been completed, the support plate and the detachable metal layer are removed.

### BACKGROUND OF THE INVENTION

1. Field of the Invention

The present invention relates generally to a plating method without plating a conduction line, and more particularly, to a method for fabricating a carrier board having no conduction line.

2. The Prior Arts

Nowadays, electronic products are fast developed with the trend toward lightness, slimness, and multifunction. Correspondingly, this demands greater I/O numbers for the dies of the electronic products. Currently, the flip-die technology has been used in packaging many high class electronic products, and therefore the packaging densities thereof have also been increased correspondingly.

However, in order to satisfy the demand of a carrier board having a high layout density for a smaller distance between conductor lines (especially those would be useless upon completion of the plating process), more layout area is desired to be reserved. Specifically, according to the conventional technology, when plating a nickel/gold layer onto circuit layer which packages the carrier board, a current should be provided to the carrier board, especially the circuit layer to be plated. As such, a conduction line should be provided in connection with the circuit layer for providing the current thereto. However, although the circuit layer can be completely encapsulated with the plating nickel/gold layer by doing so, the conduction line unfortunately resides in the carrier board and occupies the layout area even after the plating process. If the conduction line is designed with a narrower width for the purpose of saving the area occupied by the conduction line, it may cause an uneven thickness of the plated nickel/gold layer. Therefore, narrowing the width of the conduction layer is not a good solution in improving the layout density.

In order to further improve the effective area for layout, many manufacturers have proposed different plating methods without plating conduction lines. However, according to some of them, when neglecting the conduction layer, the plating nickel/gold layer fails to completely encapsulate the circuit layer, in which the plating nickel/gold layer is configured on the surface of the circuit layer rather than the lateral sides of the circuit layer.

Currently, there are several major plating methods without plating a conduction line including non-plating line (NPL) technology, bottom plating, full body gold (FBG) gold pattern plating (GPP) technology, selective gold plating, technology and electroless nickel auto-catalyst gold (ENAG) technology. However, all of these methods have their own disadvantages.

The NPL technology provides a method for plating a nickel/gold layer on electrical contact pads of a substrate without plating a conduction line on the substrate. With respect to the NPL technology, it provides a conductive film which constructs a current transmitting path to electrically connect the electrical contact pads of the substrate, and therefore configures the plating nickel/gold configuration of the electrical contact pads of the die packaging substrate. In such a way, the NPL technology provides a solution to solve the problem of insufficient circuit layout area due to the disposition of the conduction line.

The complicated process and the relative high production cost is one disadvantage of the NPL and bottom plating. If the layout pattern has independent nets which are disposed on the same layer, the fabricating process become too complicated to conduct, in which when one of the nets is not connected to another side (e.g., ball pad, or inner layer power and ground) of the layer via a via hole, it causes restrictions to the design the fabrication thereof.

GPP provides a process other than that of NPL, by which the substrate electrical contact pad can be plated with nickel/gold layer without providing the conduction line on the surface of the substrate, and thus eliminating the affection of the layout of the conduction line. However, the GPP technology requires to plate nickel/gold on to all of the circuit, so that the production cost thereof is relatively high, and the adhesion performance between the solder mask and the gold layer is weaker than that between copper and such a solder mask.

Selective gold plating technology disadvantageously has a narrow operation window. When performing a selective gold plating process, a permeable plating may occur, which drastically decreases the yield. As to the ENAG method, it has the drawback in that the chemical solution can not be conveniently controlled. Sometimes the chemical solution may attack the solder mask, and other problems such as skip-plate, plating gold on the substrate, thin edge-effect may happen. Further, it may even cause a black pad defect, which may cause a poor bondability between the solder balls and the pads so that the solder balls may fall off.

Further, there are also other manufacturers proposed to provide a temporary conduction line, which can not only avoid the above-mentioned problems, but also remove the conduction line later so as to achieve a carrier board with a higher layout density.

Taiwanese Patent Pub. No. I262750 discloses a fabricating method for “a packaging substrate”, and Taiwanese Patent Pub. No. I240400 discloses “a process for electroplating metal layer without plating lines after the solder mask process”, in which a plating current is transmitted to the pad to be plated from a backside of the carrier board via a plating metal layer on a core via hole, and the plating metal layer is removed after the plating process. This technology performs an electroplating process regarding to a certain part of the entire metal layer, and configures a passivation layer thereby. However, this technology is not suitable when dealing with an independent pad which is not connected with other metal unit of the carrier board.

### SUMMARY OF THE INVENTION

A primary objective of the present invention is to provide a method for fabricating a carrier board having no conduction line. The method utilizes a detachable support plate for providing a plating current, and removes the detachable support plate after the plating process is completed.

For achieving the foregoing objective, the present invention provides a method for fabricating a carrier board having no conduction line. The fabricating method includes: providing a support plate having a detachable metal layer; providing a plating current via the support plate and the detachable metal layer to plate on the detachable metal layer to in sequence configure an etching resist layer and a plating metal layer; and then gradually completing other circuit layers by a compression laminating process with the support plate providing the plating current. After the entire plating process has been completed, the support plate and the detachable metal layer are removed.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A through 1J are schematic diagrams illustrating a method for fabricating a carrier board having no conduction line according to an embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

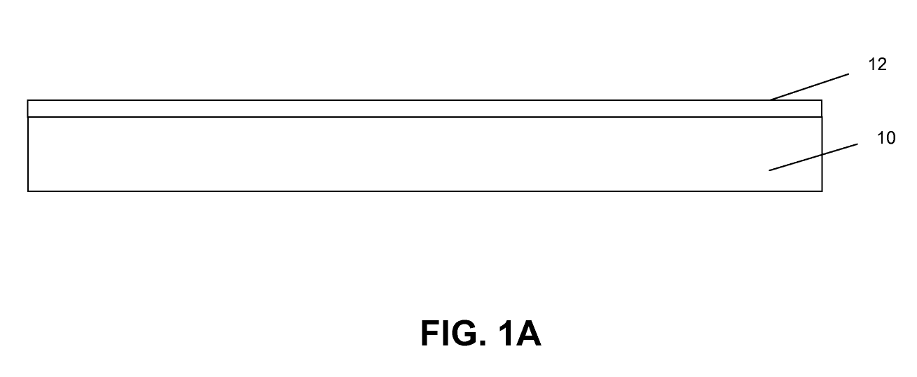

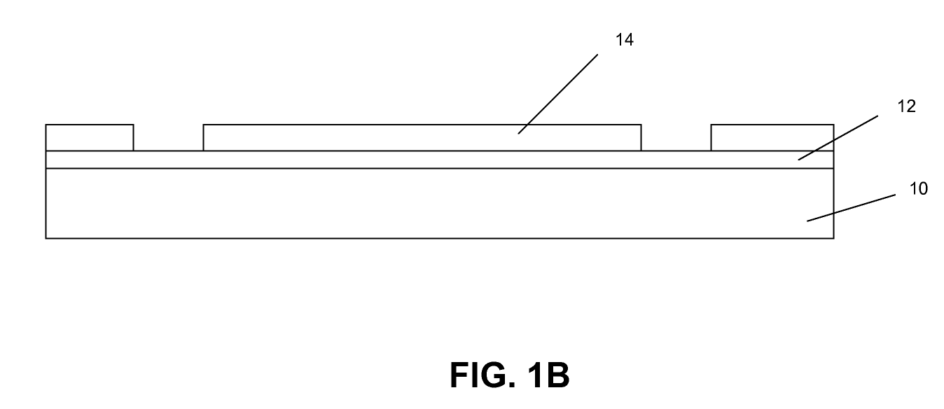

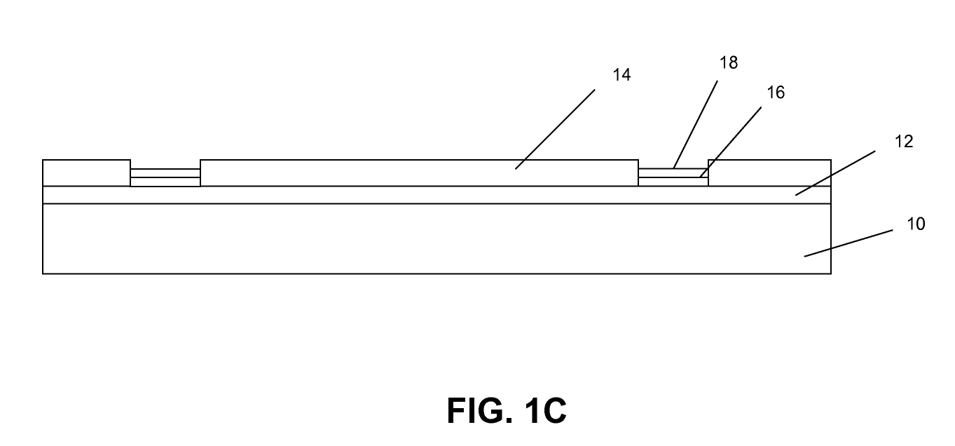

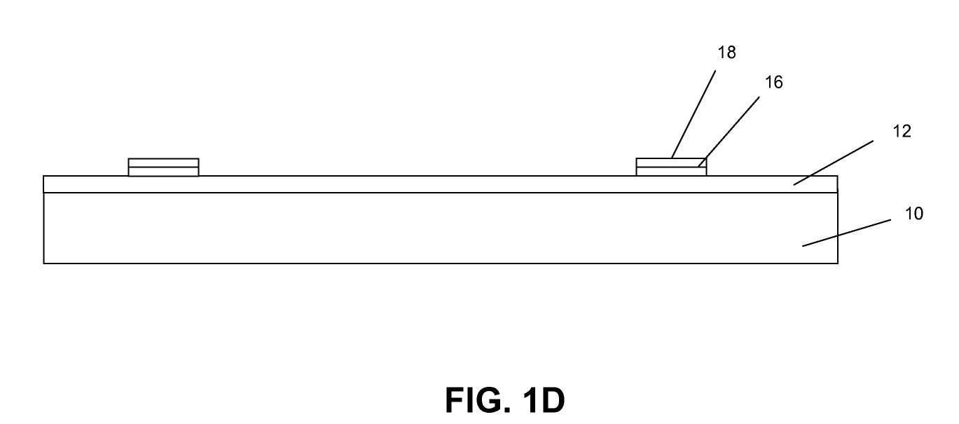

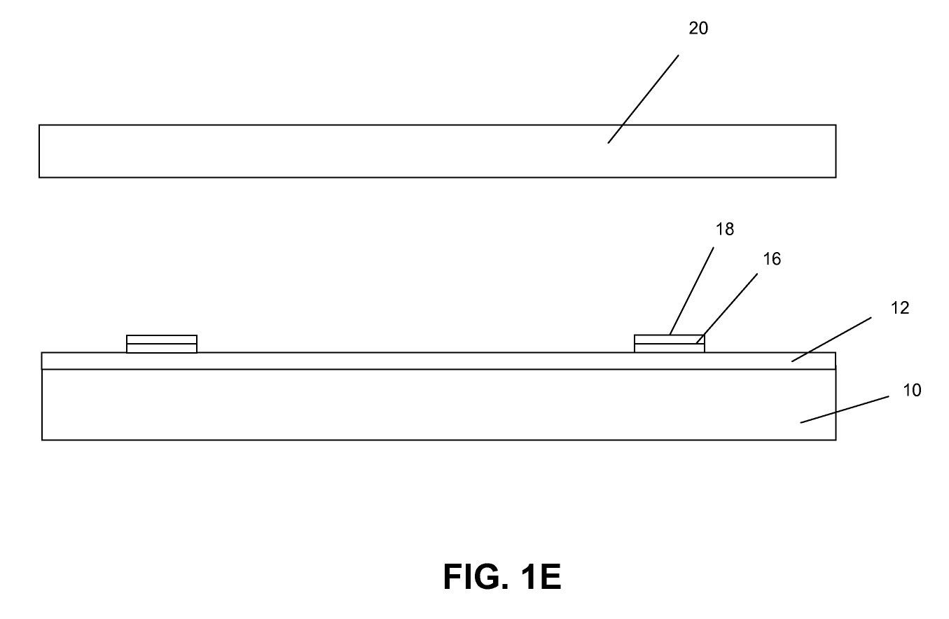

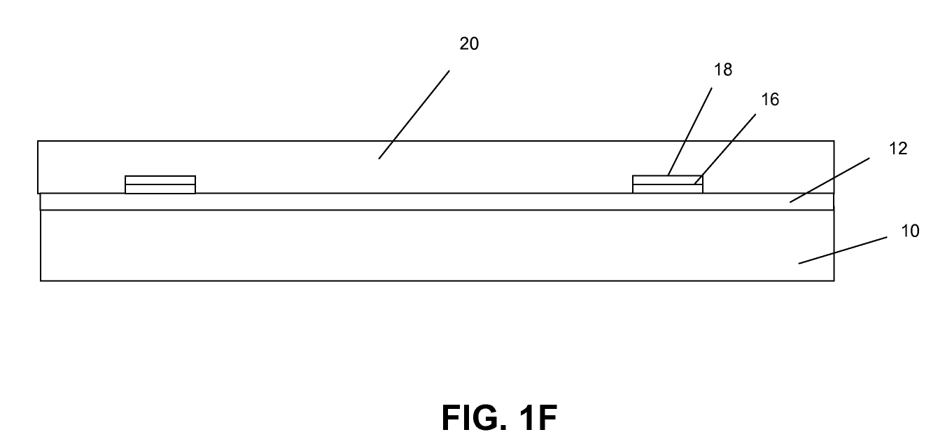

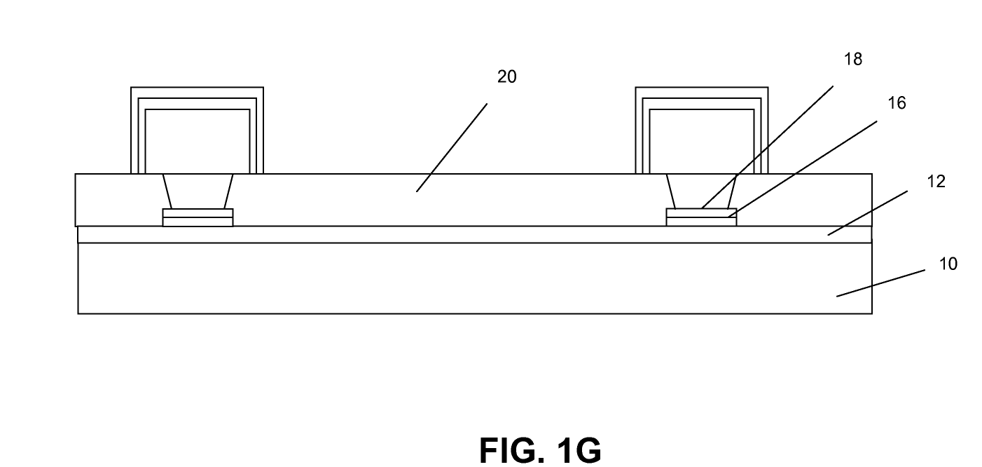

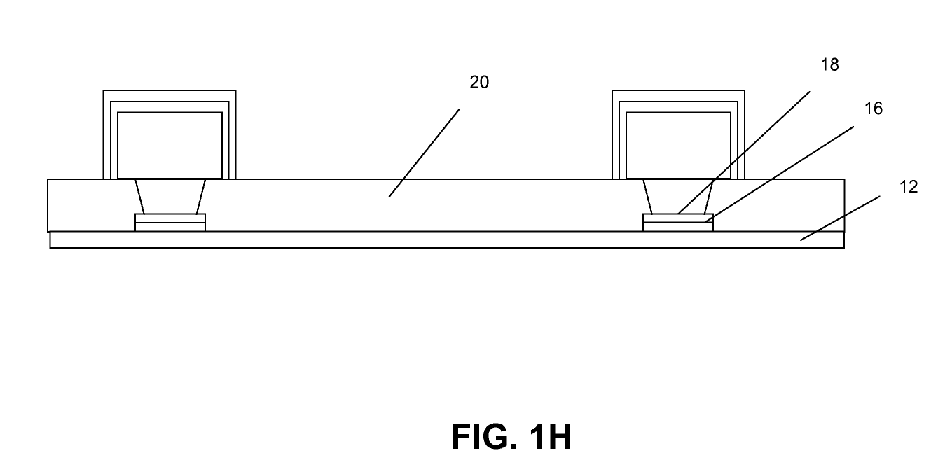

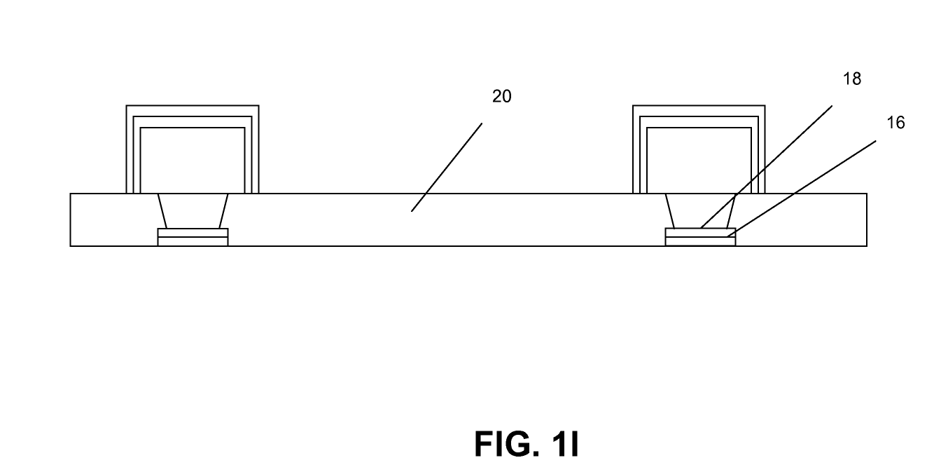

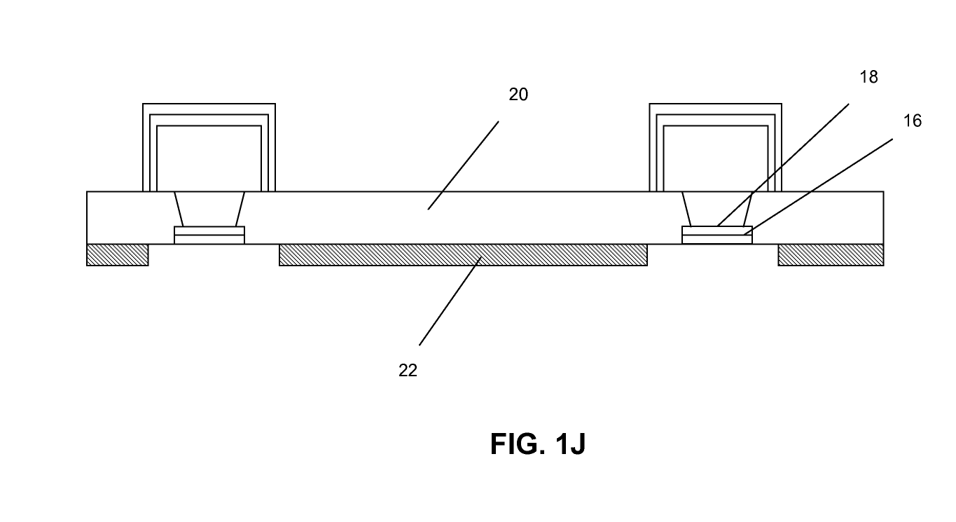

Referring to FIGS. 1A through 1J, there are shown a method for fabricating a carrier board having no conduction line according to an embodiment of the present invention. As shown in FIG. 1C, the support plate 10 can be made of an electrical conductive material. The detachable metal layer 12 is made of copper. The etching resist layer 16 is made of nickel. The plating metal layer 18 is made of copper. In such a way, because of the material characteristics of the support plate 10 and the detachable metal layer 12 and the difference therebetween, the support plate 10 can be conveniently detached from the carrier board as shown in FIG. 1G As shown in FIG. 1H, because of the material characteristics of etching resist layer 16 and the detachable metal layer 12 and the difference therebetween, when etching to remove the detachable metal layer 12, the etching resist layer 16 will not be damaged, and meanwhile the plating metal layer 18 is protected from being damaged.

Briefly, in the method for fabricating the carrier board having no conduction line according to an embodiment of the present invention, firstly as shown in FIG. 1A, the support plate 10 having the detachable metal layer 12 is prepared. Then, as shown in FIG. 1C, a plating current is provided via the support plate 10 and the detachable metal layer 12 to plate on the detachable metal layer 12 to in sequence configure an etching resist layer 16 and a plating metal layer 18. Then, other circuit layers are gradually completed by a compression laminating process as shown in FIG. 1E with the support plate 10 providing the plating current. After the entire plating process has been completed, the support plate 10 and the detachable metal layer 12 are removed. As shown in FIG. 1J, a process of providing a solder mask layer is further executed to achieve the carrier board having no conduction line.

Specifically, as shown in FIG. 1B, in order to define the position of the circuit, a patterning photo resist layer 14 is configured on the detachable metal layer 12. Then, as shown in FIG. 1C, the plating current is provided via the support plate 10 and the detachable metal layer 12 to plate on the detachable metal layer 12 according to the patterning photo resist layer 14 to in sequence configure the etching resist layer 16 and the plating metal layer 18, i.e., the circuit layer. Then, as shown in FIG. 1D, the patterning photo resist layer 14 is removed away.

In order to further complete other layers of the carrier board, as shown in FIGS. 1E through 1F, a dielectric plastic film 20 is compressed onto the detachable metal layer 12 and the plating metal layer 18 configured thereon, so as to cover the detachable metal layer 12 and the plating metal layer 18. In order to allow the etching resist layer 16, the plating metal layer 18 which are portions of the circuit layer to transmit signals, one or more times of processes including boring and filling and plating should be executed to configure interlayer via holes, as shown in FIG. 1G After completing the filling and plating processing, a grinding/polishing process may be provided, or a nickel/gold plating process may be provided. It should be noted that, all of the aforementioned plating processes can be completed with the plating current provided by the support plate 10 and the detachable metal layer 12, and without any conduction line or temporary conduction line for providing plating current.

As shown in FIGS. 1H through 1I, after the entire plating process has been completed and when there is no need for providing the plating current by the support plate 10 and the detachable metal layer 12, the support plate 10 and the detachable metal layer 12 can be removed to expose the dielectric plastic film 20 and the etching resist layer 16. And finally, as shown in FIG. 1J, after removing the support plate 10 and the detachable metal layer 12, the solder mask layer 22 is configured on the exposed dielectric plastic layer 20.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A method for fabricating a carrier board having no conduction line, comprising:
providing a support plate having a detachable metal layer;
configuring a patterning photo resist layer on the detachable metal layer;
providing a plating current via the support plate and the detachable metal layer to plate on the detachable metal layer according to the patterning photo resist layer to in sequence configure an etching resist layer and a plating metal layer;
removing the patterning photo resist layer; and
compressing a dielectric plastic film onto the detachable metal layer and the plating metal layer configured thereon,
wherein when the support plate and the detachable metal layer are not needed for transmitting the plating current, the support plate, the detachable metal layer are sequentially removed away to expose out the dielectric plastic film and the etching resist layer.

2. The method according to claim 1, wherein the support plate is made of an electrical conductive material.

3. The method according to claim 1, wherein the detachable metal layer is made of copper.

4. The method according to claim 1, wherein the etching resist layer is made of nickel.

5. The method according to claim 1, wherein the plating metal layer is made of copper.

6. The method according to claim 1, further comprising:
after removing the support plate, the detachable metal layer, configuring a solder mask layer on the exposed dielectric plastic film.
